(19) United States
(12) Patent Application Publication
(10) Pub. No.: US 2015/0322561 A1
(43) Pub. Date: Nov. 12, 2015

(54) METAL DEPOSITED FILM AND MANUFACTURING INTERMEDIATE AND RELATED MANUFACTURING METHOD THEREOF

(71) Applicant: Shiquan Cai, (US)

(72) Inventor: Shiquan Cai, Kunshan (CN)

(21) Appl. No.: 14/647,376

(22) PCT Filed: Nov. 30, 2012
(86) PCT No.: PCT/CN2012/085701

§ 371 Date: May 26, 2015

(30) Foreign Application Priority Data
Nov. 26, 2012 (CN) 201210487140.7

(51) Int. Cl. C23C 14/00; C23C 14/14; C23C 14/12; C23C 14/02

(52) U.S. Cl. CPC C23C 14/0005; C23C 14/028; C23C 14/14; C23C 14/12

(57) ABSTRACT

The present invention relates to a metal deposited film consisting of a first high polymer material layer, a metal deposited film, a second high polymer material layer and a hydrolysable high polymer material layer which are sequentially formed or attached from bottom to top; both the X axles and the Y axles of the metal deposited layer, the first high polymer material layer and the second high polymer material layer are wavy; and both the X axle and the Y axle of the lower surface of the hydrolysable high polymer material layer are wavy. Preferably, the second high polymer material layer is coated onto the metal deposited layer. The hydrolysable high polymer material layer is coated onto the second high polymer material layer. The present invention also relates to a manufacturing intermediate and a related manufacturing method for the metal deposited film, wherein a carrier film is adopted for manufacturing. The metal deposited film is smart in design and concise in structure, and its metal deposited layer can expand or stretch more uniformly, and thus has considerably high elasticity without cracks and can be transferred and attached to a stereoscopic curved surface of an object more easily; and in addition, the metal deposited layer is smart and convenient to manufacture and is applicable to large-scale popularization and application.

### TECHNICAL FIELD

The present invention relates to the technical field of films, in particular to the technical field of metal deposited films, more particularly a metal deposited film as well as a manufacturing intermediate and a related manufacturing method thereof.

### BACKGROUND ART

A metal deposited layer on the metal deposited film used on the market at present is easy to crack because of being not even enough and cannot be easily transferred and attached onto a stereoscopic curved surface of an object.

Therefore, a metal deposited film needs to be provided, and its metal deposited layer can expand or stretch more uniformly, and thus has considerably high elasticity without cracks and can be transferred and attached to the stereoscopic curved surface of the object more easily.

### SUMMARY OF THE PRESENT INVENTION

The present invention provides a metal deposited film as well as a manufacturing intermediate and a related manufacturing method thereof in order to overcome the defects abovementioned in the prior art. The metal deposited film is smart in design and concise in structure, and its metal deposited layer can expand and stretch more uniformly, and thus has considerably high elasticity without cracks and can be transferred and attached to the stereoscopic curved surface of the object more easily; and in addition, the metal deposited film is smart and convenient to manufacture and applicable to large-scale popularization and application.

In order to achieve the above objectives, at the first aspect of present invention, it provides a metal deposited film, characterized by consisting of a first high polymer material layer, a metal deposited layer, a second high polymer material layer and a hydrolysable high polymer material layer which are sequentially formed or attached from bottom to top, wherein both the X axles and the Y axles of the first high polymer material layer, the metal deposited layer and the second high polymer material layer are wavy, and both the X axle and the Y axle of the hydrolysable high polymer material layer are wavy.

Preferably, the said second high polymer material layer is coated onto said metal deposited layer.

Preferably, the said hydrolysable high polymer material layer is coated onto said second high polymer material layer.

At the second aspect of present invention, it provides a manufacturing intermediate for the metal deposited film, characterized by comprising a carrier film, a first high polymer material layer, a metal deposited layer, a second high polymer material layer and a hydrolysable high polymer material layer which are sequentially formed or attached from bottom to top, wherein both the X axles and the Y axles of said first high polymer material layer, said metal deposited layer and said second high polymer material layer are wavy, and both the X axle and the Y axle of the lower surface of said hydrolysable high polymer material layer are wavy, and both the X axle and the Y axle of the upper surface of said carrier film are wavy.

Preferably, the said second high polymer material layer is coated onto said metal deposited layer.

Preferably, the said hydrolysable high polymer material layer is coated onto said second high polymer material layer.

Preferably, the said first high polymer material layer is coated onto said carrier film.

At the third aspect of present invention, it provides a manufacturing method for the metal deposited film according to claim 1, characterized by comprising the following steps:

(1) processing the upper surface of the carrier film to ensure that both its X axle and its Y axle are wavy, and thus a wavy concave-convex surface is obtained;

(2) forming or attaching a first wavy concave-convex high polymer material, namely the first high polymer material layer, to the wavy concave-convex surface of the carrier film;

(3) depositing the wavy concave-convex metal layer, namely the metal deposited layer, on the first high polymer material layer;

(4) forming or attaching a wavy concave-convex high polymer material layer, namely the second high polymer material layer, on the metal deposited layer;

(5) forming or attaching a hydrolysable high polymer material film, namely the hydrolysable high polymer material layer, on the second high polymer material layer; and

(6) separating the carrier film from the first high polymer material layer to obtain said metal deposited film.

Preferably, in the step (5), said hydrolysable high polymer material layer is coated onto said second high polymer material layer; or in the step (4), said second high polymer material layer is coated onto said metal deposited layer; or in the step (2), said first high polymer material layer is coated onto said carrier film.

The present invention has the beneficial effects that:

1. the metal deposited film of the present invention consists of a first high polymer material layer, a metal deposited layer, a second high polymer material layer and a hydrolysable high polymer material layer which are sequentially formed or attached from bottom to top, wherein both the X axles and the Y axles of the first high polymer material layer, the metal deposited layer and the second high polymer material layer are wavy; both the X axle and the Y axle of the lower surface of the hydrolysable high polymer material layer are wavy; the metal deposited film is smart in design and concise in structure, and its metal deposited layer can expand or stretch more uniformly, and thus has considerably high elasticity without cracks and can be transferred and attached onto the stereoscopic curved surface of the object more easily, and therefore, the metal deposited film is applicable to large-scale popularization and application.

2. The manufacturing intermediate for the metal deposited film of the present invention comprises a carrier film, a first high polymer material layer, a metal deposited layer, a second high polymer material layer and a hydrolysable high polymer material layer which are sequentially formed or attached from bottom to top, wherein both the X axles and the Y axles of the first high polymer material layer, the metal deposited layer and the second high polymer material layer are wavy; both the X axle and the Y axle of the lower surface of the hydrolysable high polymer material layer are wavy; both the X axle and the Y axle of the upper surface of the carrier film are wavy; and the manufacturing intermediate is smart in design and concise in structure, and its metal deposited layer can expand or stretch more uniformly, and thus has considerably high elasticity without cracks and can be transferred and attached into the stereoscopic curved surface of the object more easily, and therefore, the manufacturing intermediate is applicable to large-scale popularization and application.

3. According to the manufacturing method for the metal deposited film of the present invention, the wavy metal deposited film (a high polymer coating) with a double-faced structure is manufactured by employing a single-faced wavy carrier film, and the manufacturing method is smart and convenient in manufacturing and applicable to large-scale popularization and application.

### BRIEF DESCRIPTION OF DRAWINGS

FIG. 1 is a local front view schematic diagram of one specific embodiment of the manufacturing intermediate for the metal deposited film of the present invention.

### SPECIFIC EMBODIMENTS

The following embodiments will be specifically illustrated in detail in order to understand the technical contents of the present invention more clearly. Wherein, the same components are marked by employing the same drawing signs.

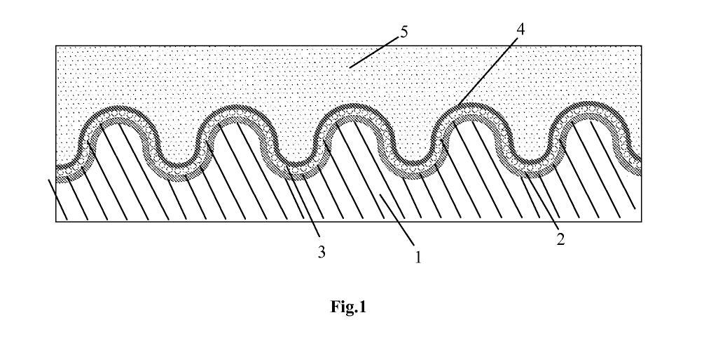

As shown in FIG. 1, the manufacturing intermediate for the metal deposited film of the present invention comprises a carrier film 1, a first high polymer material layer 2, a metal deposited layer 3, a second high polymer material layer 4 and a hydrolysable high polymer material layer 5 which are sequentially formed or attached from bottom to top; both the X axles and the Y axles of the first high polymer material layer 2, the metal deposited layer 3 and the second high polymer material layer 4 are wavy; both the X axle and the Y axle of the lower surface of the hydrolysable high polymer material layer 5 are wavy; and both the X axle and the Y axle of the upper surface of the carrier film 1 are wavy.

An OPP (oriented polypropylene) film or PET (polyethylene terephthalate) film and the like (GuangDong Decro Film New Materials CO., LTD) can be employed as the carrier film 1.

The first high polymer material layer 2 can be made of polyurethane (Gaoding Fine Chemical (kunshan) Co., Ltd).

The metal deposited layer 3 can be any appropriate metal deposited layer, such as an aluminum deposited layer, a copper deposited layer, a gold deposited layer or a silver deposited layer.

The second high polymer material layer 4 can be made of polyurethane (Gaoding Fine Chemical (kunshan) Co., Ltd).

The hydrolysable high polymer material 5 can be made of polyvinyl alcohol (Beijing Organic Chemical Plant).

The hydrolysable high polymer material layer 5 is formed or attached to the second high polymer material 4 and can employ any appropriate structure. In the specific embodiments of the present invention, the hydrolysable high polymer material 5 is coated onto the second high polymer material layer 4. It is obvious that an adhesion manner, for instance, can be employed as well.

The second high polymer material layer 4 is formed or attached to the metal deposited layer 3 and can employ any appropriate structure. In the specific embodiments of the present invention, the second high polymer material layer 4 is coated onto the metal deposited layer 3. An adhesion manner, for instance, can be employed as well.

The first high polymer material layer 2 is formed or attached to the carrier film 1 and can employ any appropriate structure. In the specific embodiments of the present invention, the first high polymer material layer 2 is coated onto the carrier film 1. An adhesion manner, for instance, can be employed as well.

The metal deposited film of the present invention can be obtained just by separating the carrier film 1 from the first high polymer material layer 2.

The manufacturing method for the metal deposited film is briefly illustrated as below:

1. the upper surface of the carrier film 1 is processed to ensure that both its X axle and its Y axle are wavy, and thus a wavy concave-convex surface is obtained;

2. a wavy concave-convex high polymer material layer, namely the first high polymer material layer 2 is formed or attached to the wavy concave-convex surface of the carrier film 1;

3. a wavy concave-convex metal layer, namely the metal deposited layer 3 is deposited on the first high polymer material layer 2;

4. a wavy concave-convex high polymer material layer, namely the second high polymer material layer 4 is formed or attached to the metal deposited layer 3; and at this moment, the first high polymer material 2, the metal deposited layer 3 and the second high polymer material layer 4 define a complete high-elasticity, telescopic and deformable metal coating;

5. a hydrolysable high polymer material film, namely the hydrolysable high polymer material layer 5 can be formed or attached to the second high polymer material layer 4, and therefore, both the X axle and the Y axle of the lower surface of the hydrolysable high polymer material layer 5 are wavy; and the high-elasticity hydrolysable high polymer material layer 5 assists the metal coating formed by the three layers abovementioned to expand or stretch uniformly, and thus the metal coating can be easily transferred and attached to the stereoscopic surface of the object; and

6. The metal deposited film is obtained by separating the carrier film 1 from the first high polymer material layer 2.

The manufacturing intermediate for the metal deposited film abovementioned can be obtained if the step 6 is not performed.

The vacuum deposition refers to a process of heating a deposited material under a certain vacuum condition, so that the deposited material is molten (or sublimated) to form steam consisting of atoms, molecules or atomic groups and is condensed on the surface of a substrate to form a film; the metal vacuum deposited layer is formed by dense configuration of small granules per se. The manufacturing method abovementioned is a novel technology for manufacturing the novel metal deposited film from the carrier film 1. The manufacturing method is a technology which is smart and convenient in manufacturing and accords with the patented technology (Chinese Patent ZL200510111618.6), so that the metal vacuum deposited layer, namely the metal deposited layer 3, on the metal deposited film can expand or stretch more uniformly, and thus has considerably high elasticity without cracks and can be transferred and attached to the stereoscopic curved surface of the object more easily.

In conclusion, the metal deposited film of the present invention is smart in design and concise in structure, and its metal deposited layer can expand or stretch more uniformly, and thus has considerably high elasticity without cracks and can be easily transferred and attached onto the stereoscopic curved surface of the object; and in addition, the metal deposited film is smart and convenient to manufacture and applicable to large-scale popularization and application.

In this description, the present invention has been described by reference to the specific embodiments. However, it is obvious that various amendments and transformations can be made yet without departing from the spirit and the scope of the present invention. Therefore, the description and the attached drawings should be considered to be illustrative, but not restrictive.

1. A metal deposited film, characterized by consisting of a first high polymer material layer, a metal deposited layer, a second high polymer material layer and a hydrolysable high polymer material layer which are sequentially formed or attached from bottom to top, wherein both the X axles and the Y axles of the first high polymer material layer, the metal deposited layer and the second high polymer material layer are wavy, and both the X axle and the Y axle of the hydrolysable high polymer material layer are wavy.

2. A metal deposited film according to claim 1, characterized in that said hydrolysable high polymer material layer is coated onto said second high polymer material layer.

3. The metal deposited film according to claim 1, characterized in that said second high polymer material layer is coated onto said metal deposited layer.

4. A manufacturing intermediate for the metal deposited film, characterized by comprising a carrier film, a first high polymer material layer, a metal deposited layer, a second high polymer material layer and a hydrolysable high polymer material layer which are sequentially formed or attached from bottom to top, wherein both the X axles and the Y axles of said first high polymer material layer, said metal deposited layer and said second high polymer material layer are wavy, and both the X axle and the Y axle of the lower surface of said hydrolysable high polymer material layer are wavy, and both the X axle and the Y axle of the upper surface of said carrier film are wavy.

5. The manufacturing intermediate for the metal deposited film according to claim 4, characterized in that said hydrolysable high polymer material layer is coated onto said second high polymer material layer.

6. The manufacturing intermediate for the metal deposited film according to claim 4, characterized in that said second high polymer material layer is coated onto said metal deposited layer.

7. The manufacturing intermediate for the metal deposited film according to claim 4, characterized in that said first high polymer material layer is coated onto said carrier film.

8. A manufacturing method for the metal deposited film according to claim 1, characterized by comprising the following steps:
(1) processing the upper surface of the carrier film to ensure that both its X axle and its Y axle are wavy, and thus a wavy concave-convex surface is obtained;
(2) forming or attaching a first wavy concave-convex high polymer material, namely the first high polymer material layer, to the wavy concave-convex surface of the carrier film;
(3) depositing the wavy concave-convex metal layer, namely the metal deposited layer, on the first high polymer material layer;
(4) forming or attaching a wavy concave-convex high polymer material layer, namely the second high polymer material layer, on the metal deposited layer;
(5) forming or attaching a hydrolysable high polymer material film, namely the hydrolysable high polymer material layer, on the second high polymer material layer; and
(6) separating the carrier film from the first high polymer material layer to obtain said metal deposited film.

9. The manufacturing method according to claim 8, characterized in that in the step (5), said hydrolysable high polymer material layer is coated onto said second high polymer material layer; or in the step (4), said second high polymer material layer is coated onto said metal deposited layer; or in the step (2), said first high polymer material layer is coated onto said carrier film.
